(19) United States
(12) Patent Application Publication
(10) Pub. No.: US 2021/0242120 A1
(43) Pub. Date: Aug. 5, 2021

(54) Circuit module consisting of a plurality of components interconnected in an electrically conductive manner, and a method for producing a circuit module of this kind

(71) Applicant: Gentherm GmbH, Odelzhausen (DE)

(72) Inventors: Marco Ranalli, Augsburg (DE); Rüdiger Spillner, Augsburg (DE)

(21) Appl. No.: 17/269,335

(22) PCT Filed: May 21, 2019
(86) PCT No.: PCT/DE2019/000144

§ 371 Date: Feb. 18, 2021

(30) Foreign Application Priority Data
Aug. 22, 2018 (DE) 10 2018 006 625.9

(51) Int. Cl. H01L 23/498

(52) U.S. Cl. CPC H01L 23/49833; H01L 23/3121; H01L 23/49811; H01L 23/4985

(57) ABSTRACT

A circuit module comprising at least one integrated semiconductor circuit which is enclosed or encapsulated in an isolating housing and has a plurality of electrical terminal contacts which are led out of the isolating housing, and which are connected in an electrically conductive manner to contact surfaces of a planar intermediate carrier. The integrated semiconductor circuit together with its housing lies on or against a first side of the planar intermediate carrier. The planar intermediate carrier has edge-side outer contacts on a second side opposite the first side. The outer contacts are connected to corresponding terminal contacts of a film-like line carrier in an electrically conductive manner. The planar intermediate carrier having connection lines between the contact surfaces and the outer contacts.

### FIELD

The present invention relates to a circuit module consisting of a plurality of components interconnected in an electrically conductive and a method for producing a circuit module of this kind.

### BACKGROUND

Problems can arise when conventional semiconductor components such as integrated semiconductor circuits are to be mounted on flexible line carriers, for example, on films, since both wire bond connections and soldered connections having relatively stiff wire lines which are led out of a plastic housing of the semiconductor component are usually mechanically overloaded, particularly when the flexible line carrier is severely deformed in an installation situation or is subject to further movements after its installation. Different solutions have already been made in order to solve these problems.

For example, DE 41 29 964 A1 discloses a method for producing an electrically conductive fastening of an integrated circuit with contact pieces on a flexible printed circuit. An elastic plastic film has conductor tracks on its surface, which are provided with hump-like thickenings, with which the electrical contact to the contact pieces of the electrical circuit can be made. The arrangement formed in this way can be fastened to a printed circuit designed as a flat plate having conductor tracks and connected thereto in an electrically conductive manner.

JP 2000 77 835 A discloses an electronic component having a plurality of terminals which are led out of a housing and which are mounted on a circuit board by means of webs or connecting sections. The webs or connecting sections can here be formed by film sections.

### SUMMARY

The primary aim of the present invention can be seen in providing a universally usable mounting option, a method for its implementation and a corresponding arrangement that make it possible to mount circuit components and/or semiconductor components on flexible line carriers without the contact connections between the circuit component or semiconductor component and the flexible line carrier equipped with conductor tracks being mechanically overstressed, particularly when the flexible line carrier is deformed.

The above aim of the invention is achieved by the subject matter of the independent claims. Further advantageous embodiments are described by the respective dependent claims.

To achieve the stated aim, the invention proposes a circuit module consisting of a plurality of components interconnected in an electrically conductive manner which comprises at least one integrated semiconductor circuit which is enclosed or encapsulated in an isolating housing and has a plurality of electrical terminal contacts which are led out of the isolating housing. In addition, the module comprises a planar intermediate carrier having contact surfaces which are connected in an electrically conductive manner to the electrical terminal contacts which are led out of the isolating housing of the integrated semiconductor circuit, wherein the integrated semiconductor circuit together with its housing lies on or against a first side of the planar intermediate carrier. Furthermore, the planar intermediate carrier has edge-side outer contacts on a second side opposite the first side having the housing of the integrated semiconductor circuit lying on or against it, which outer contacts are connected in an electrically conductive manner to corresponding terminal contacts of a film-like line carrier. In addition, it is provided that the planar intermediate carrier has connection lines between the contact surfaces and the outer contacts.

The use of a relatively rigid intermediate carrier according to the invention, on which the integrated semiconductor circuit is mounted, advantageously allows conventional semiconductor circuits with their typically relatively stiff wire contacts which are led out of a housing to be mounted on pliable, film-like line carriers by means of an intermediate carrier of this kind. These film-like line carriers are usually relatively thin and very flexible, whereby they can be used in an extremely varied manner and in a wide variety of mounting situations. Due to their flexibility, however, they are poorly suited for the direct mounting of integrated semiconductor components such as semiconductor circuits, since their relatively stiff wire legs and contacts require an installation situation with a stable carrier, otherwise there is always the risk of loss of contact due to damage to the wire legs or contacts and/or electrical contacts. Particularly, the soldered and/or glued connections usually used to make electrical contact with the terminal contacts of the electrical semiconductor circuit, which are inflexible due to its housing, require largely stable installation and use situations, since otherwise the soldered and/or glued connections are hardly capable of permanently guaranteeing the electrical contacts when there are frequent bending stresses or load changes.

In the circuit module according to the invention, the connection lines arranged on, at and/or in the planar intermediate carrier can be arranged thereon and/or run on the surface. Optionally, the connection lines can run at least along one of the two surfaces of the planar intermediate carrier. However, it is also possible for the connection lines to run on both sides along each of the two surfaces of the planar intermediate carrier. In addition, it can be advantageous when the connection lines are integrated in the planar intermediate carrier and penetrate the intermediate carrier in their course from one surface to the other. In a more complex embodiment variant of this kind, the planar intermediate carrier preferably has a thickness that enables the connection lines to run transversely and/or diagonally from one surface to the other and thus through the material of the intermediate carrier.

The relatively rigid intermediate carrier can, for example, be made from a suitable plastic, optionally from a multilayer isolating material or the like, which carries the necessary terminal contacts and connection lines on the surface and, if necessary, embedded in the material. Particularly advantageously, the connection lines running in the material of the intermediate carrier of the more complex circuit module according to the invention and embedded there can have at least one crossing point in their course from one surface to the other, but preferably also a plurality of or numerous crossing points.

Optionally, the terminal contacts of the semiconductor circuit can be connected to the contact surfaces of the intermediate carrier via wire bond connections. It is also possible to use semiconductor circuits, the terminal contacts of which are connected to the contact surfaces of the intermediate carrier via rigid wire legs and soldered connections. In both variants, the relatively stiff intermediate carrier offers the advantage of a mechanically stable connection of all electrical terminal contacts, which makes it possible to mount semiconductor circuits of this kind on relatively pliable, film-like line carriers without the electrical terminal contacts being exposed to excessive mechanical loads and thereby endangering their stability.

A further advantage of the intermediate layer of the planar intermediate carrier used in the circuit module according to the invention can be seen in the fact that in this way, crossings of lines that would be difficult to implement in the film are not only possible, but also the contacting of comparatively coarse conductor track structures, which can be combined with the significantly finer IC contacts of the semiconductor circuit, for example, in the case of films or film-like line carriers having large conductor track widths and/or large conductor track spacings (that is, a wide pitch in the mm range).

The planar intermediate carrier of the circuit module according to the invention can preferably be formed by a rigid material such as laminate or the like; however, it is also conceivable for the planar intermediate carrier to be formed by a flexible material consisting of a plurality of conductor film layers joined to one another. In such a case, the planar intermediate carrier cannot be formed by a printed circuit or a circuit board or the like, but by a multilayer film composite or by a plurality of conductor film layers, wherein these layers can be formed by associated film conductor sections or also by individual blanks. Optionally, a relatively flexible additional potting compound to be described further below can be configured as a stiffening sheath for the entire film composite having the plurality of conductor film layers including part of the housing and the semiconductor circuit encased therein. Smaller-volume sheaths of partial regions, particularly a transition region between the planar intermediate carrier and the film-like line carrier, would also be conceivable.

In this variant, the necessary through-contacts of the terminal contacts and/or the contacts between the conductor film layers can be implemented using so-called vias (for example, as rivets), but optionally also by gluing, soldering or welding, possibly also in connection with bending and/or twisting of the film, so that its contact surface can turn from bottom to top or vice versa. The through-contacts can also optionally be produced by removing the isolation layer in places (for example, by so-called “kiss-cut”).

A further advantageous variant of the circuit module according to the invention can provide that at least transition regions between the planar intermediate carrier and the film-like line carrier are at least partially embedded in a potting compound or encased thereby. It is preferably provided here that the potting compound has a flexibility which is greater than that of the planar intermediate carrier and which is equal to or less than the flexibility of the film-like line carrier.

Transition regions between the intermediate carrier and the line carrier can prove to be critical in practical use of the modules, particularly in the immediate vicinity of an edge of the relatively rigid intermediate carrier, since a configuration of this kind can damage the conductor tracks (not depicted) of the film-like line carrier when bending loads occur. Particularly, it cannot be ruled out that the conductor tracks of the film-like line carrier kink or break, or that their isolation can be damaged. In order to avoid or at least reduce a risk of this kind, the edges on the longitudinal sides of the planar intermediate carrier can be modified as a sensible measure. The circumferential edges on the second side of the intermediate carrier facing the film-like line carrier can thus be beveled, rounded or otherwise blunted, which contributes to reducing the notch effect in this transition region and can significantly reduce the risk of breakage or damage mentioned. A beveled edge of this kind can, for example, resemble a 45° bevel. This beveled edge can optionally be provided on all longitudinal sides or only in defined sections. The beveled edge can be produced by suitable shaping in the production of the intermediate carrier or also by subsequent processing, that is, by removing material or by applying material. Further measures can also be taken in order to reduce the above-mentioned risks of damage to the conductor track of the film-like line carrier. For example, an additional potting compound can be used, which can be formed, for example, by a suitable laminate or by an adhesive material. The potting compound can optionally be applied on both sides in the vicinity of the contact surfaces of the intermediate carrier. However, it may also be sufficient to apply the potting compound only to one side of the intermediate carrier and the line carrier, optionally on the first side or on the second side. The flexibility of this additional potting compound is preferably between that of the intermediate carrier and the flexibility of the line carrier, whereby an effective protection of the contact regions or contact surfaces between the two elements and thus an effective protection against undesired breakage phenomena can be created. That is, the potting compound should be more flexible than the relatively rigid intermediate carrier, but somewhat more rigid than the flexible and pliable line carrier.

Optionally, when using a potting compound of this kind, the long sides can also be designed and/or beveled or rounded in the manner described above, with which the alternative protection options can be combined. However, it is also possible to use the application of the additional potting compound as an alternative variant of protection against breakage.

The possible uses of the potting compound can be further refined or graded in a further variant of the circuit module according to the invention. A somewhat more flexible layer of a flexible potting compound can also be applied in this way, which in turn can be formed, for example, by an adhesive material, a suitable laminate or by another suitable material. The potting compound can optionally be applied to both sides in the vicinity of the contact surfaces of the intermediate carrier in this variant too. Here, too, it can alternatively suffice to apply the potting compound only to one side of the intermediate carrier and the line carrier, optionally to the first side or to the second side. The flexibility of the additional potting compound applied in the region of the contact surfaces is preferably between that of the intermediate carrier and the flexibility of the line carrier, while the flexible potting compound extending to an outer region of the line carrier is closer to the flexibility of the line carrier in terms of its flexibility.

Thus, in a variant of this kind of the circuit module, the potting compound can be used with graded flexibility or rigidity, wherein the rigidity should decrease or the flexibility or flexural slackness should increase with increasing distance from the intermediate carrier. These desired properties can be achieved in the manner described by using differently flexible materials, different material thicknesses (decreasing means more flexible), recesses in the material distribution or locally different curing or cross-linking (for example, UV exposure time).

In a further advantageous embodiment variant of the circuit module according to the invention, the terminal contacts of the semiconductor circuit can be flattened and/or widened at their connection surfaces (SMD design, surface mounted device) and thus, while avoiding the intermediate carrier, can be applied directly to corresponding terminal contact surfaces of the film-like line carrier. It should be expressly made clear at this point that the intermediate carrier can optionally be dispensed with in this embodiment variant because the special shape of the terminal contacts of the electrical semiconductor circuit allows permanent and reliable mounting directly on a film-like line carrier. The terminal contacts of the electrical semiconductor circuit can be applied here in an electrically conductive manner to the terminal contact surfaces of the film-like line carrier.

The terminal contacts can optionally be soldered to the terminal contact surfaces of the film-like line carrier. In addition, it can be advantageous when stiffening strips are placed on the upper side of the flat areas of the terminal contacts of the semiconductor circuit. These stiffening strips can be laminated, for example, on the terminal contacts or on the terminal contacts of the semiconductor circuit.

A further function of the aforementioned stiffening strip can be that the terminal contacts otherwise often cannot be plugged into their counterparts. It is only through the stiffening that sufficient force can be applied during the production of the contacts without the contacts yielding or bending on their carrier substances. Alternatively, a complex plug-in tool is often required, which can be omitted due to the design according to the invention.

In a modified embodiment variant of a circuit module of this kind, a plurality of film conductors or film conductor sections or the film-like line carriers can be combined such that multiple-row plug contacts are created and multiple-row plugs (terminals, housings, . . . ) can be fitted or connected. The stiffening is preferably located between the planes formed by the adjacent line carriers.

In addition, it should be pointed out that in the case of stiffening, measures to reduce the risk of breakage in the region of the contact surfaces in the form of beveled edges, additional potting compounds or a combination of these measures can also be provided as an alternative or in addition.

To achieve the above-mentioned aim, the invention further proposes a method for producing a circuit module, particularly a circuit module as has already been explained and defined above in different embodiment variants. This circuit module according to the invention is formed from a plurality of components interconnected in an electrically conductive manner, namely from at least one integrated semiconductor circuit which is enclosed or encapsulated in an isolating housing and has a plurality of electrical terminal contacts which are led out of the isolating housing and which are connected in an electrically conductive manner to contact surfaces of a planar intermediate carrier, from a planar intermediate carrier and from a film-like line carrier. The method provides that the integrated semiconductor circuit together with its housing is placed on or against a first side of the planar intermediate carrier, which planar intermediate carrier has edge-side outer contacts on a second side opposite the first side having the housing of the integrated semiconductor circuit lying on or against it and has connection lines between the contact surfaces and the outer contacts, which outer contacts of the intermediate carrier in turn are connected in an electrically conductive manner to corresponding terminal contacts of a film-like line carrier.

The use of the relatively rigid intermediate carrier, which carries the integrated semiconductor circuit and stabilizes all of its electrical terminals, makes it possible to mount conventional semiconductor circuits on pliable, film-like line carriers without breaking or damaging the electrical terminal wires and terminal contacts. Since the film-like line carriers that are typically used are generally relatively thin and very flexible, they can be used in a variety of ways and in a wide variety of mounting situations. Due to their flexibility, however, they are poorly suited for the direct mounting of integrated semiconductor components such as semiconductor circuits, since their relatively stiff wire legs and contacts require an installation situation with a stable carrier, otherwise there is always the risk of loss of contact due to damage to the wire legs or contacts and/or electrical contacts. Particularly, the soldered and/or glued connections usually used to make electrical contact with the terminal contacts of the electrical semiconductor circuit, which are inflexible due to its housing, require largely stable installation and use situations, since otherwise the soldered and/or glued connections are hardly able to permanently guarantee the electrical contacts when there are frequent bending stresses or load changes. The method according to the invention provides a practical solution for this.

An alternative embodiment of the method according to the invention provides that the terminal contacts of the semiconductor circuit are flattened and/or widened at their connection surfaces (SMD design—surface mounted device) and thus, while avoiding the intermediate carrier, can be applied directly to corresponding terminal contact surfaces of the film-like line carrier. The intermediate carrier can optionally be dispensed with in this embodiment variant because the special shape of the terminal contacts of the electrical semiconductor circuit allows permanent and reliable mounting directly on a film-like line carrier. The terminal contacts of the electrical semiconductor circuit can be applied here in an electrically conductive manner to the terminal contact surfaces of the film-like line carrier. The terminal contacts can optionally be soldered to the terminal contact surfaces of the film-like line carrier. In addition, it can be advantageous when stiffening strips are placed on the upper side of the flat areas of the terminal contacts of the semiconductor circuit. These stiffening strips can be laminated, for example, on the terminal contacts or on the terminal contacts of the semiconductor circuit.

In addition, it should be pointed out at this point that all aspects, variants and specifics that were mentioned and described in connection with the various design variants of the circuit module according to the invention can also be seen in connection with the method according to the invention for producing a circuit module of this kind. The same also applies vice versa, so that those aspects that were mentioned in connection with the method described above can also be in connection with the circuit module. This also stipulates that the disclosure of the invention through the above description is to be viewed as an overall disclosure without a mandatory and mutually exclusive assignment to the circuit module according to the invention in its various embodiment variants or to the method according to the invention for producing the circuit module being given or defined.

### BRIEF DESCRIPTION OF THE FIGURES

In the following, exemplary embodiments are intended to explain the invention and its advantages in more detail with reference to the accompanying figures. The proportions of the individual elements to one another in the figures do not always correspond to the real proportions, since some forms are simplified and other forms are depicted enlarged in relation to other elements for better illustration.

FIG. 1A shows a schematic plan view of an embodiment variant of a circuit module according to the invention.

FIG. 1B shows, in a schematic cross section, the structure of a first embodiment variant of the circuit module from FIG. 1A together with its essential components and their interaction.

FIG. 1C shows, in a schematic cross section, the structure of a second embodiment variant of the circuit module from FIG. 1A together with its essential components and their interaction.

FIG. 1D shows, in a schematic cross section, the structure of a third embodiment variant of the circuit module from FIG. 1A together with its essential components and their interaction.

FIG. 1E shows, in a schematic cross section, the structure of a fourth embodiment variant of the circuit module from FIG. 1A together with its essential components and their interaction.

FIG. 1F shows, in a schematic cross section, the structure of a fifth embodiment variant of the circuit module from FIG. 1A together with its essential components and their interaction.

FIG. 2A shows a side view and a plan view of an embodiment variant of terminal contacts of a semiconductor circuit of the circuit module according to the invention.

FIG. 2B shows the connection of the contact variant according to FIG. 2A with the conductor tracks of a film-like line carrier.

FIG. 2C shows a schematic side view of a further connection variant for the terminal contacts, which are stabilized on the line carrier with the addition of a stiffening strip applied there.

FIG. 2D shows a schematic side view of an alternative connection variant for the terminal contacts, which are implemented in a multilayer component.

### DETAILED DESCRIPTION

Identical reference symbols are used for identical or identically acting elements of the invention. Furthermore, for the sake of clarity, only reference symbols which are necessary for the description of the respective figure are depicted in the individual figures. The depicted embodiments merely represent examples of how the device according to the invention or the method according to the invention can be designed and do not constitute a final limitation.

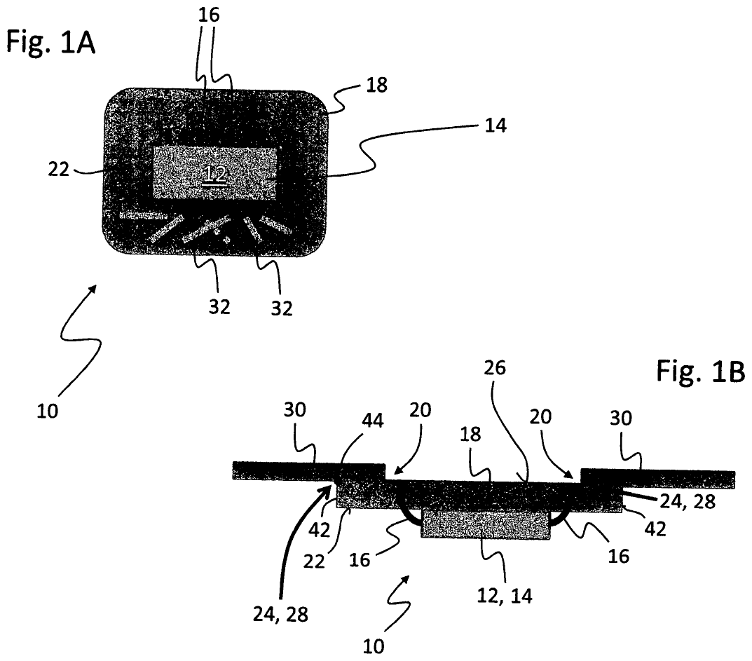

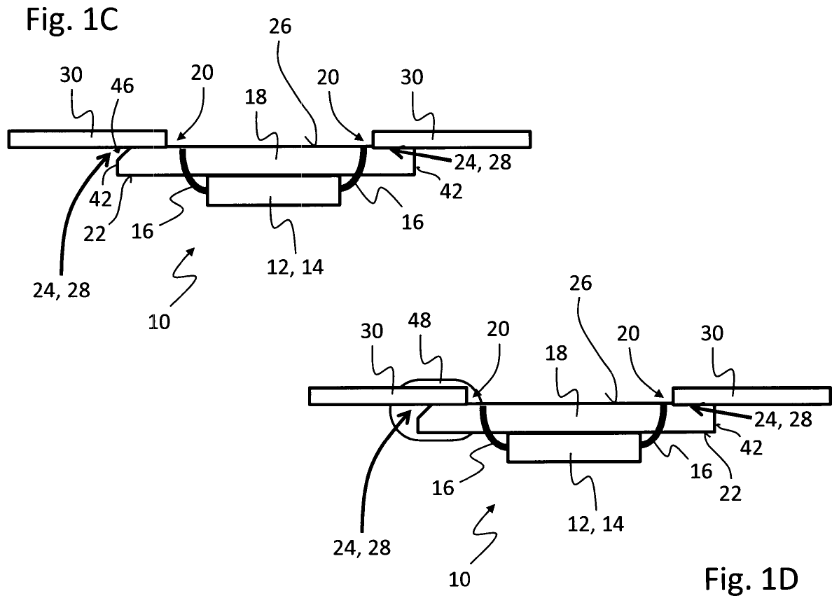

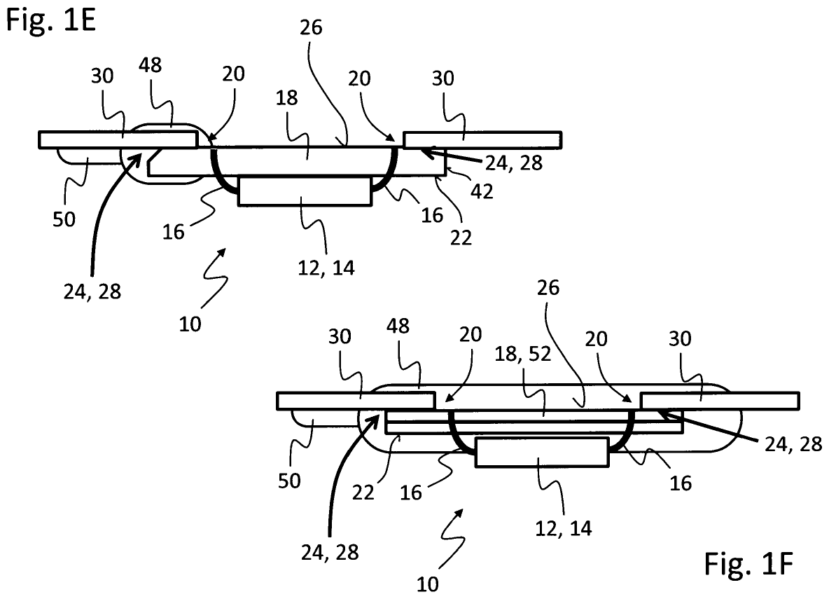

FIG. 1A shows a schematic plan view of an embodiment variant of a circuit module 10 according to the invention, while the schematic cross section of FIG. 1B illustrates a first variant of the structure of the circuit module 10 together with its essential components and their interaction.

The circuit module 10 shown in such a way in FIGS. 1A, 1B. 1C, 1D, 1E and 1F comprises a plurality of components interconnected in an electrically conductive manner, namely an integrated semiconductor circuit 12 which is enclosed or encapsulated in an isolating housing 14 and which has a plurality of electrical terminal contacts 16 which are led out of the isolating housing 14. In principle, the semiconductor circuit 12 together with its enclosing housing 14 can represent the most varied of integrated electronic components. The semiconductor circuit can be, for example, a so-called ASIC (Application-Specific Integrated Circuit), which can mean highly integrated computer circuits (so-called SoC, system-on-chip) or other integrated circuits designed for specific applications.

The circuit module 10 furthermore comprises a planar intermediate carrier 18 having contact surfaces 20 which are connected in an electrically conductive manner to the electrical terminal contacts 16 which are led out of the isolating housing 14 of the integrated semiconductor circuit 12. In addition, FIGS. 1B and 1C to 1E show that the integrated semiconductor circuit 12 together with the underside of its housing 14 normally lying on or against a first side 22 of the planar intermediate carrier 18. The planar intermediate carrier 18 has edge-side outer contacts 24 on a second side 26 opposite the first side 22 having the housing 14 of the integrated semiconductor circuit 12 lying on or against it, which outer contacts are connected in an electrically conductive manner to corresponding terminal contacts 28 of a film-like line carrier 30. In addition, it is provided that the planar intermediate carrier 18 has connection lines 32 between its contact surfaces to the semiconductor circuit 12 and its outer contacts 24 to the film-like line carrier 30.

The intermediate carrier 18 shown in the plan view of FIG. 1A without the film-like line carrier 30, on which the semiconductor circuit 12 together with its isolating housing 14 is mounted and contacted, is relatively rigid and in this way allows the mounting of the mechanically sensitive semiconductor circuit 12 together with its edge-side (or possibly top-side) terminal contacts 16 led out of the housing 14 and typically relatively stiff wire contacts and formed from wire on the comparatively thin and flexible film-like line carrier 30 by means of the mechanically stable, dimensionally stable and resilient intermediate carrier 18. Since the relatively thin and thus very flexible usable film-like line carrier 30 is only poorly suited for direct mounting of the integrated semiconductor circuit, the relatively stiff wire legs and contacts 16 of which require an installation situation with a stable carrier, the stable intermediate carrier 18 provides this necessary carrier structure.

The connection lines 32 arranged on, at and/or in the planar intermediate carrier 18 are arranged at least at the surface thereon and/or run there. Optionally, the connection lines 32 can run at least along one of the two surfaces, that is, the first side 22 and/or the second side 26 of the planar intermediate carrier 18 (see the view of the first side 22 in FIG. 1A). In addition, it is also possible to integrate the connection lines 32 in the planar intermediate carrier 18 so that they penetrate the intermediate carrier 18 in their course from one surface or from one side 22 to the other side 26. In a more complex embodiment variant of this kind, the planar intermediate carrier 18 expediently has a thickness that enables transverse and/or diagonal courses of the connection lines 32 from one side to the other or from one surface to the other and thus through the material of the intermediate carrier 18.

The relatively rigid intermediate carrier 18 can, for example, be made from a suitable plastic, optionally from a multilayer isolating material or the like, which carries the necessary terminal contacts 20, 24 and connection lines 32 on the surface and, if necessary, embedded in the material. Particularly advantageously, the connection lines 32 running in the material of the intermediate carrier 18 of the more complex circuit module 10 according to the invention and embedded there can have at least one crossing point in their course from one surface to the other or from one side 22 to the other side 26, but preferably also a plurality of or numerous crossing points, which are isolated from one another if necessary or make a contact in an electrically conductive manner.

A further advantage of the intermediate layer of the planar intermediate carrier 18 used can be seen in the fact that in this way, crossings of lines that would be difficult to implement in the film are not only possible, but also the contacting of comparatively coarse conductor track structures, which can be combined with the significantly finer IC contacts of the semiconductor circuit 14, for example, in the case of films or film-like line carriers 30 having large conductor track widths and/or large conductor track spacings (that is, a wide pitch in the mm range).

In the first embodiment variant of the circuit module 10 according to the invention shown in FIG. 1B, the planar intermediate carrier 18, which also carries the semiconductor circuit 12, has pronounced edges 44 on its longitudinal sides 42.

However, in practical use of the modules 10, this transition point between the intermediate carrier 18 and the line carrier 30 can prove to be critical, particularly in the immediate vicinity of the edge 44, since a configuration of this kind can damage the conductor tracks (not depicted) of the film-like line carrier 30 when bending loads occur. Particularly, the conductor tracks of the film-like line carrier 30 can kink or break, or their isolation can be damaged.

In order to avoid or at least reduce this risk, the edges 46 on the longitudinal sides 42 of the planar intermediate carrier 18 can be modified as a sensible measure, as is shown in the illustration in FIG. 1C, which is to be considered as a second embodiment variant of the circuit module 10 according to the invention. In this variant, the circumferential edges 46 on the second side 26 of the intermediate carrier 18 facing the film-like line carrier 30 can be beveled, rounded or otherwise blunted, which contributes to reducing the notch effect in this transition region and significantly reduces the risk of breakage or damage mentioned.

In the illustration of FIG. 1C, only the left side is drawn as a beveled edge 46, similar to a 45° bevel. However, this beveled edge 46 can be provided on all longitudinal sides 42 or optionally only in defined sections. The beveled edge 46 can be produced by suitable shaping in the production of the intermediate carrier 18 or also by subsequent processing, that is, by removing material or by applying material. The rest of the structure of the second variant of the circuit module 10 shown in FIG. 1C does not differ from the first variant shown in FIG. 1B, so that a repeated explanation of the elements and components labeled with reference numbers can be dispensed with at this point.

In order to reduce the above-mentioned risks of damage to the conductor track of the film-like line carrier 30, further measures can also be taken, as the schematic representation of FIG. 1D illustrates, which shows a third variant of the circuit module 10 according to the invention. This variant thus provides an additional potting compound 48, which can be formed, for example, by a suitable laminate or also by an adhesive material. The potting compound 48 can optionally be applied on both sides in the vicinity of the contact surfaces 20 of the intermediate carrier 18 according to FIG. 1D. However, it may also be sufficient to apply the potting compound 48 only to one side of the intermediate carrier 18 and the line carrier 30, optionally on the first side 22 or on the second side 26. The flexibility of this additional potting 48 compound is preferably between that of the intermediate carrier 18 and the flexibility of the line carrier 30, whereby an effective protection of the contact regions or contact surfaces 20 between the two elements 18 and 30 and thus an effective protection against undesired breakage phenomena can be created. That is, the potting compound 48 should be more flexible than the relatively rigid intermediate carrier 18, but somewhat more rigid than the flexible and pliable line carrier 30.

Optionally, the longitudinal sides 42 according to FIG. 1D can be designed in the same way as in the second variant shown in FIG. 1C, with which the alternative protection options are combined. However, it is also possible to design the longitudinal sides 42 in the same way as in the first variant shown in FIG. 1B, so that the application of the additional potting compound 48 can be viewed as an alternative protection variant against breakage.

The rest of the construction of the third variant of the circuit module 10 shown in FIG. 1D does not differ from the first variant shown in FIG. 1B or from the second variant shown in FIG. 1C, so that a repeated explanation of the elements and components labeled with reference numbers can be dispensed with at this point.

As the schematic representation of FIG. 1E illustrates, which shows a fourth variant of the circuit module 10 according to the invention, the third variant shown in FIG. 1D can be further refined or graded. This fourth variant provides the additional potting compound 48 corresponding to the third variant according to FIG. 1D and a somewhat more flexible layer of a flexible potting compound 50, which, for example, can in turn be formed by an adhesive material, a suitable laminate or by another suitable material. In the fourth variant, too, the potting compound 48 can optionally be applied to both sides in the vicinity of the contact surfaces 20 of the intermediate carrier 18 according to FIG. 1E, as in the third variant shown in FIG. 1D. Here, too, it can alternatively suffice to apply the potting compound 48 only to one side of the intermediate carrier 18 and the line carrier 30, optionally to the first side 22 or to the second side 26. The flexibility of the additional potting compound 48 applied in the region of the contact surfaces 20 is preferably between that of the intermediate carrier 18 and the flexibility of the line carrier 30, while the flexible potting compound 50 extending to an outer region of the line carrier 30 is closer to the flexibility of the line carrier 30 in terms of its flexibility.

Thus, in the fourth variant of the circuit module 10 shown in FIG. 1E, the potting compound 48 and 50 can be applied with graduated flexibility or stiffness, wherein the stiffness should decrease or the flexibility or flexural slackness should increase as the distance from the intermediate carrier 18 increases. These desired properties can be achieved in the manner described, for example, by using differently flexible materials 48 and 50, different material thicknesses (decreasing means more flexible; see FIG. 1E), recesses in the material distribution (not shown) or locally different curing or cross-linking (for example, UV exposure time). Optionally, the longitudinal sides 42 according to FIG. 1E can be designed in the same way as in the second variant shown in FIGS. 1C and 1n the third variant shown in FIG. 1D, with which the alternative protection options are combined. However, it is also possible to design the longitudinal sides 42 in the same way as in the first variant shown in FIG. 1B, so that the application of the additional potting compound 48 and the flexible potting compound 50 can be viewed as an alternative protection variant against breakage.

The rest of the construction of the fourth variant of the circuit module 10 shown in FIG. 1E does not differ from the first variant shown in FIG. 1B or from the second and third variants shown in FIGS. 1C and 1D, so that a repeated explanation of the elements and components labeled with reference numbers can be dispensed with at this point.

FIG. 1F further shows a fifth variant of a circuit module 10 according to the invention, in which the planar intermediate carrier 18 is not formed by a printed circuit or a circuit board or the like, but by a multilayer film composite or by a plurality of conductor film layers 52, wherein these layers 52 can be formed by associated film conductor sections or also by individual blanks. Optionally, the relatively flexible additional potting compound 48 here can be designed in the manner shown as a stiffening sheath for the entire film composite with the plurality of conductor film layers 52 together with part of the housing 14 and the semiconductor circuit 12 encased therein. Sheaths having a smaller volume than shown in FIG. 1F would also be conceivable.

The necessary through-contacts of the terminal contacts 16 and/or between the conductor film layers 52, which the latter are not depicted in the drawing here, can be implemented, for example, as so-called vias (for example, as rivets), but optionally also by gluing, soldering or welding, optionally also in connection with bending and/or twisting the film, so that its contact surface can turn from bottom to top or vice versa. The through-contacts can also optionally be produced by removing the isolation layer in places (for example, by so-called “kiss-cut”).

The rest of the structure of the fifth variant shown in FIG. 1F largely corresponds to the variants already explained above, wherein here, too, a graded configuration of the potting compound 48 and 50 with regard to its flexibility is possible in accordance with the fourth variant shown in FIG. 1E, so that optionally an outer section of a more flexible potting compound 50 can be applied in the region of the film-like line carrier 30.

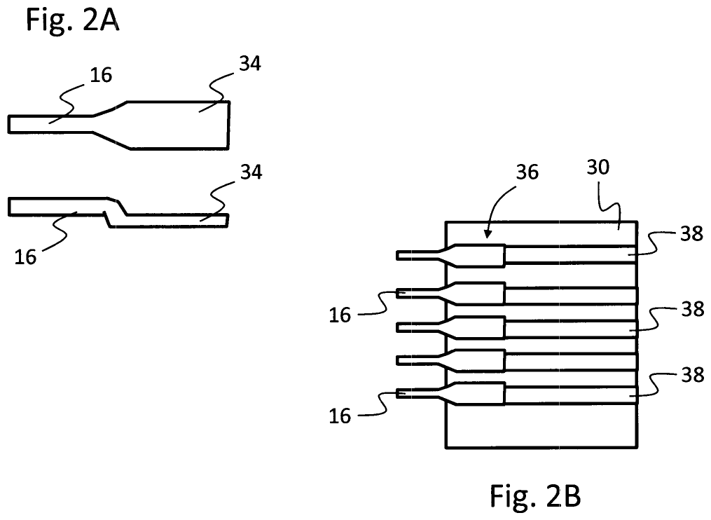

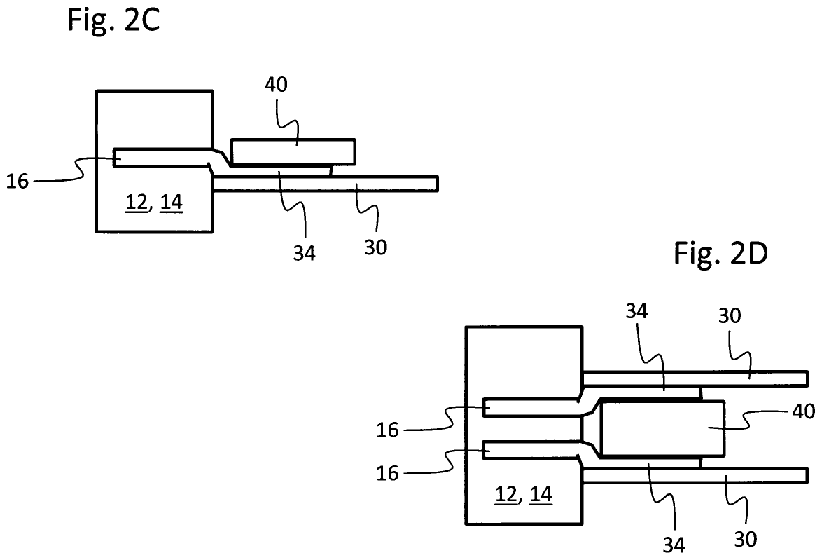

The schematic detailed view of FIG. 2A shows a side view and a plan view of an embodiment variant of the terminal contacts 16 of the semiconductor circuit 12 of the circuit module 10 according to the invention (see FIGS. 1A to 1F). The schematic plan view of FIG. 2B shows the connection of the contact variant according to FIG. 2A to the conductor tracks 38 of the film-like line carrier 30. Optionally, however, a laminate material can be used instead of a film-like line carrier 30 of this kind. FIG. 2C also shows a schematic side view of a further connection variant for the terminal contacts 16, which are stabilized on the line carrier 30 with the addition of a stiffening strip 40 applied there. In addition, FIG. 2D shows a schematic side view of a further connection variant for the terminal contacts 16, which are formed here as a multi-row plug.

In the further embodiment variants of the circuit module 10 according to the invention shown in various details and views in FIGS. 2A, 2B, 2C and 2D, the terminal contacts 16 of the semiconductor circuit 12 led out laterally from the housing 14 (see the side view of FIG. 2C) are flattened and widened at their end contact sides 34 (see FIG. 2A), as is provided in many cases with so-called SMD components (SMD—surface mounted device). With these widened and flattened contact sides 34 of their terminal contacts 16, the semiconductor circuits 12 are applied directly to corresponding terminal contact surfaces 36 of the film-like line carrier 30 or the laminate material and soldered there, avoiding the stable intermediate carrier shown in FIGS. 1A and 1B. In this embodiment variant, the intermediate carrier 18 according to FIG. 1 can be dispensed with, because the special shape of the terminal contacts 34 of the electrical semiconductor circuit 12 allows permanent and reliable mounting directly on the correspondingly designed conductor tracks 38 of the film-like line carrier 30 or the laminate material.

As illustrated in FIG. 2C, the terminal contacts 16 can be soldered with their flattened and widened end contact sides 34 on corresponding terminal contact surfaces of the conductor tracks 38 of the film-like line carrier 30 or of the laminate material. In addition, it can be advantageous when stiffening strips 40 are placed on or applied to the upper sides of the flattened contact sides 34 of the terminal contacts 16 of the semiconductor circuit 12. These stiffening strips 40 can, for example, be laminated onto the terminal contacts 16, 34 of the semiconductor circuit 12 and ensure mechanical stabilization and stiffening of the electrically conductive connections between the semiconductor circuit 12 and the pliable or flexible line carrier 30.

A further function of the stiffening strip 40 in FIG. 2C is that the terminal contacts 16 otherwise often cannot be plugged into their counterparts. It is only through the stiffening 40 that sufficient force can be applied during the production of the contacts 16 without the contacts already yielding or bending on their carrier substances. Alternatively, a complex plug-in tool is often required, which can be omitted due to the design according to FIG. 2C and also according to FIG. 2D.

FIG. 2D illustrates a modified embodiment variant in which a plurality of film conductors or film conductor sections or film-like line carriers 30 are combined so that multiple-row plug contacts are created and multiple-row plugs (terminals, housings, . . . ) can be fitted or connected. In this case, the stiffening 40, in the manner shown, is preferably located between the planes formed by the adjacent line carriers 30.

In addition, it should be pointed out that the measures to reduce the risk of breakage in the region of the contact surfaces 20 corresponding to FIGS. 1C, 1D, 1E and/or 1F can also be sensibly applied in the stiffening 40 corresponding to FIGS. 2C and 2D as an alternative or in addition. This concerns the beveled edge 46 (FIG. 1C), the additional potting compound 48 (FIG. 1D) and/or the flexible potting compound 50 that can be used in addition (FIGS. 1E and 1F).

The invention has been described with reference to a preferred embodiment. However, it is conceivable for a person skilled in the art that modifications or changes can be made to the invention without departing from the scope of protection of the following claims.

### LIST OF REFERENCE SYMBOLS

10 module, circuit module
12 semiconductor circuit
14 housing
16 terminal contacts (of the semiconductor circuit)
18 intermediate carrier, planar intermediate carrier
20 contact surfaces (of the intermediate carrier)
22 first side (of the intermediate carrier)
24 outer contacts, edge-side outer contacts (of the intermediate carrier)
26 second side (of the intermediate carrier)
28 terminal contacts (of the line carrier)
30 line carrier, film-like line carrier
32 connection lines (of the intermediate carrier)
34 contact sides, end contact sides
36 terminal contact surfaces (of the film-like line carrier)
38 conductor tracks (of the film-like line carrier)
40 strip, stiffening strip, laminated strip
42 longitudinal side (of the intermediate carrier)
44 edge (of the longitudinal side)
46 beveled edge
48 potting compound, additional potting compound
50 flexible pouting compound
52 layer, conductor film layer

1) A circuit module comprising:
at least one integrated semiconductor circuit enclosed or encapsulated in an isolating housing, the at least one integrated semiconductor circuit comprises a plurality of electrical terminal contacts which are led out of the isolating housing, the plurality of electrical terminal contacts are connected in an electrically conductive manner to contact surfaces of a planar intermediate carrier, the at least one integrated semiconductor circuit together with the isolating housing lies on or against a first side of the planar intermediate carrier, the planar intermediate carrier has edge-side outer contacts on a second side that is opposite the first side, the outer contacts are connected to corresponding electrical terminal contacts of a film-like line carrier in an electrically conductive manner, and the planar intermediate carrier connection lines between the contact surfaces and the outer contacts.

2) The circuit module according to claim 1, wherein the connection lines of the planar intermediate carrier are on a surface of the planar intermediate carrier, run along one of the first side and the second side, or are on both of the first side and the second side of the planar intermediate carrier.

3) The circuit module according to claim 1, wherein the connection lines are integrated in the planar intermediate carrier and penetrate the planar intermediate carrier in their course from one of the surfaces to another of the surfaces or from the first side to the second side or from the second side to the first side.

4) The circuit module according to claim 3, wherein the connection lines have at least one crossing point in their course from one of the surfaces to the other surface or from the first side to the second side or from the second side to the first side.

5) The circuit module according to claim 1, wherein the electrical terminal contacts of the semiconductor circuit are connected to the contact surfaces of the planar intermediate carrier via wire bond connections and/or via rigid wire legs and soldered connections.

6) The circuit module according to claim 1, wherein the planar intermediate carrier is formed by a rigid material by a flexible material consisting of a plurality of conductor film layers that are joined together.

7) The circuit module according to claim 1, wherein transition regions between the planar intermediate carrier and the film-like line carrier are at least partially embedded in a potting compound or encased thereby.

8) The circuit module according to claim 7, wherein the potting compound has a flexibility which is greater than that of the planar intermediate carrier and which is equal to or less than the flexibility of the film-like line carrier.

9) The circuit module according to claim 1, wherein the electrical terminal contacts of the semiconductor circuit are flattened and/or widened at their connection surface, the electrical terminal contacts avoid the planar intermediate carrier, the electrical terminal contacts are applied directly on the corresponding electrical terminal contact surfaces of the film-like line carrier.

10) The circuit module according to claim 9, wherein the electrical terminal contacts are connected in an electrically conductive manner to the electrical terminal contact surfaces of the film-like line carrier, the electrical terminal contacts are soldered or otherwise connected to the electrical terminal contact surfaces.

11) The circuit module according to claim 9, wherein stiffening strips are placed on upper sides of the connection surfaces of the electrical terminal contacts of the semiconductor circuit.

12) The circuit module according to claim 11, wherein the stiffening strips are laminated on the electrical terminal contacts of the semiconductor circuit.

13) A method for producing a circuit module which is formed from a plurality of components interconnected in an electrically conductive manner, from at least one integrated semiconductor circuit which is enclosed or encapsulated in an isolating housing and has a plurality of electrical terminal contacts which are led out of the isolating housing, which are connected in an electrically conductive manner to contact surfaces of a planar intermediate carrier, the integrated semiconductor circuit together with the isolating housing being placed on or against a first side of the planar intermediate carrier, the planar intermediate carrier has edge-side outer contacts on a second side opposite the first side, and has connection lines between the contact surfaces and the edge-side outer contacts, the edge-side outer contacts are connected in an electrically conductive manner to corresponding electrical terminal contacts.

14) The method according to claim 13, wherein the electrical terminal contacts of the semiconductor circuit are flattened and/or widened at their connection surfaces, the electrical terminal contacts avoid the planar intermediate carrier, the electrical terminal contacts are applied directly on corresponding terminal contact surfaces.

15) The circuit module according to claim 2, wherein the connection lines are integrated in the planar intermediate carrier and penetrate the planar intermediate carrier in their course from one of the surfaces to another of the surfaces or from the first side to the second side or from the second side to the first side,

16) The circuit module according to claim 15, wherein the connection lines have at least one crossing point in their course from one of the surfaces to the other surface or from the first side to the second side or from the second side to the first side.

17) The circuit module according to claim 16, wherein the electrical terminal contacts of the semiconductor circuit are connected to the contact surfaces of the planar intermediate carrier via wire bond connections and/or via rigid wire legs and soldered connections.

18) The circuit module according to claim 17, wherein transition regions between the planar intermediate carrier and the film-like line carrier are at least partially embedded in a potting compound or encased thereby, wherein the potting compound has a flexibility which is greater than that of the planar intermediate carrier and which is equal to or less than the flexibility of the film-like line carrier.

19) The circuit module according to claim 18, wherein the electrical terminal contacts of the semiconductor circuit are flattened and/or widened at their connection surfaces, the electrical terminal contacts avoid the planar intermediate carrier, the electrical terminal contacts are applied directly on the corresponding electrical terminal contact surfaces of the film-like line carrier, wherein the electrical terminal contacts are connected in an electrically conductive manner to the electrical terminal contact surfaces of the film-like line carrier.

20) The circuit module according to claim 19, wherein stiffening strips are placed on upper sides of the connection surfaces of the electrical terminal contacts of the semiconductor circuit, the stiffening strips are laminated on the electrical terminal contacts of the semiconductor circuit.
